(19) United States
(12) Patent Application Publication
(10) Pub. No.: US 2013/0182383 A1
(43) Pub. Date: Jul. 18, 2013

(54) METHOD FOR FORMING SEALED ELECTRICAL FEEDTHROUGHS THROUGH AN ENCAPSULATION PACKAGE AND ENCAPSULATION PACKAGE PROVIDED WITH AT LEAST ONE SUCH ELECTRICAL FEEDTHROUGH

(71) Applicant: Francois Colbeau, Veurey Voroize (FR)

(72) Inventor: Francois Colbeau, Veurey Voroize (FR)

(21) Appl. No.: 13/742,764

(22) Filed: Jan. 16, 2013

(30) Foreign Application Priority Data
Jan. 17, 2012 (FR) 1200144

(51) Int. Cl. H05K 5/02; H05K 13/00

(52) U.S. Cl. CPC H05K 5/0217; H05K 13/0084
USPC 361/679.01; 228/124.1

(57) ABSTRACT

A method for forming sealed electrical feedthroughs through an encapsulation package, especially for an electronic, optical, or optoelectronic component, including forming a through opening in one of the package walls, and advantageously the bottom of said package; and soldering on this opening, a plate made of cofired ceramic having the electric connections transiting therethrough.

### FIELD OF THE INVENTION

The present disclosure belongs to the field of sealed encapsulation packages, and more specifically to that of detectors, especially of electromagnetic radiations, and more specifically cooled infrared radiations.

### BACKGROUND OF THE INVENTION

In the field of infrared detection at low temperature, that is, implementing quantum phenomena, the detector should be cooled down to very low temperatures, typically ranging between 50 and 200 K.

For this purpose, such a detector is conventionally associated with a cryostatic enclosure also called cryostat, enabling, according to the detector usage temperature, to cool the latter via a cold finger, supplied either with liquid helium, or with liquid air, or even with liquid nitrogen, or again by a cryogenerator device.

Further, the generator itself is generally encapsulated in a sealed package, in vacuum.

One of the different difficulties encountered with this type of detector is the issue resulting from the need for electrical connectors, that is, from the conveying of electric signals generated by the detector outside of the sealed package containing it, to enable them to be processed.

Indeed, most often, such connector elements have to run through the package without affecting the tightness thereof, to preserve the vacuum therein.

Actually, and to date, different technologies are implemented to ensure this connector crossing.

Such techniques comprise, first and foremost, the cofired ceramic technique. This technique may be implemented in two manners, respectively illustrated in FIGS. 1 and 2, both showing simplified cross-section views of a component encapsulation package.

In the first embodiment, the package is defined by a base 1 made of FeCoNi alloy, typically Kovar®, due to its small thermal expansion coefficient. Base 1 further receives a peripheral frame 4 made of HTCC cofired ceramic (the acronym standing for High Temperature Cofired Ceramic), as well as a peripheral frame 3 made of Kovar®. Base 1, peripheral frame 4, and peripheral frame 3 are soldered together. Then, the assembly thus formed has a cap or frame 2 for closing the package installed thereon by laser welding.

Within the package thus defined, a component 5 is attached before closing by bonding or low-temperature soldering on base 1.

Reference numeral 6 is used to designate a wire electric connection, originating from component 5, and reaching the level of lower frame 4 made of cofired ceramic, providing a feedthrough for the signal to pass to the outside of the package by means of gold vias or tracks.

In the second embodiment illustrated in FIG. 2, Kovar® base 1 is replaced with a base 7 made of cofired ceramic. The rest of the package remains substantially identical to the previous embodiment, and said base is this time used to provide a sealed electric feedthrough for the electric connections originating from the component.

In both embodiments, the cofired ceramic, be it placed at the base level or at the lower peripheral frame level, all at once has a mechanical function, a function of package cap or package bottom securing, and an electric function, that is, the transfer of the connections originating from the component. Although both technologies are presently well controlled and have a number of advantages, especially in terms of simplicity and efficiency, the mechanical soldering with a Kovar® frame providing the desired tightness, they however have the major disadvantage of limiting the package size and thus the size of the component(s) that it is capable of enclosing.

Indeed, despite the use of Kovar®, which alloy is known for its low thermal expansion coefficient, there remain problems of differential expansion of the ceramic and of this material, which rapidly become prohibitive as soon as dimensions of 60 millimeters×60 millimeters are exceed for the tight package. Indeed, the differential expansion becomes too large between Kovar® and the ceramic when the parts are soldered together, typically at a temperature close to 800° C.

Another technology is also used. It comprises using a cofired ceramic insert, which here again is used as a sealed electrical feedthrough. Two embodiments of this technology have been shown in relation with FIGS. 3 and 4.

In FIG. 3, ceramic insert 18 is arranged at the level of one of the lateral walls of base 10 defining the package in cooperation with upper cap 12. The insert is soldered on said lateral wall.

In FIG. 4, insert 19 is soldered at the level of the bottom of base 10 of the package.

Whatever the embodiment of this second technology, there is no size limitation. However, this technology has the disadvantage of a relative weak connection between the insert and the base. Indeed, if it is inadvertently pressed on one of the insert edges, this may tilt the insert with respect to its bearing area on the lateral wall, thus risking altering the tightness of the resulting package. Further, the implementation is made more complex since a metallization and a soldering on the surface and on the side of the ceramic insert are needed.

### SUMMARY OF THE INVENTION

The present invention aims at overcoming these different disadvantages.

It first aims at a method for forming sealed electrical feedthroughs through an encapsulation package, especially for an electronic, optical, or optoelectronic component.

The method comprises:
advantageously forming a through opening in one of the package walls, and advantageously the bottom of said package; and
soldering on this opening a plate made of cofired ceramic having the electric connections transiting therethrough from the component towards the outside of the package.

It can be understood that due to the method thus implemented, the ceramic plate no longer ensures any mechanical function, its function being assigned to the sole passage of the electric feedthrough, in addition to the closing of the package to ensure the vacuum.

Further, due to the face-to-face soldering of the ceramic plate, instead of a face-to-side soldering, the installing technique is facilitated and further, the package tightness is optimized. Indeed, the ceramic plate is soldered at its periphery over a distance corresponding to the periphery of the through opening made at the bottom of the base. Typically, the soldering is performed on the circumference of the ceramic plate over a distance of at most 2 millimeters.

The present invention also aims at a package for encapsulating a component, especially an electronic, optical, or optoelectronic component.

According to the present invention, the package is provided with a through opening made at the level of its bottom or of one of its walls, closed by a plate made of cofired ceramic, soldered at its lateral edges defining said through opening, said plate ensuring the electrical feedthrough resulting from electric connections originating from the component.

The present invention thus enables to overcome the problem of limitation of the size of cryostats due to differential Kovar®/ceramic expansions and to thus significantly gain size, especially for the component. Accordingly, the cryostat itself may see its size increase. It then becomes possible to encapsulate larger components with the HTCC cofired ceramic technology and thus, without implementing technologies using an insert.

Indeed, the opening made at the bottom of the package may have any dimension since the ceramic plate is anyway sized according to the characteristics of said dimensions.

The foregoing features and advantages of the present invention will now be discussed in the following non-limiting description of a specific embodiment, in relation with the accompanying drawings.

### BRIEF DESCRIPTION OF THE DRAWINGS

FIG. 1 is a simplified representation in cross-section view of a package formed according to a prior art cofired ceramic technology.

FIG. 2 is a view similar to FIG. 1 of another embodiment of this technology.

FIG. 3 is a simplified representation in cross-section view of a package implementing the prior art cofired ceramic technology.

FIG. 4 is a simplified representation of a variation of FIG. 3.

FIG. 5 is a simplified cross-section view of a package according to the present invention.

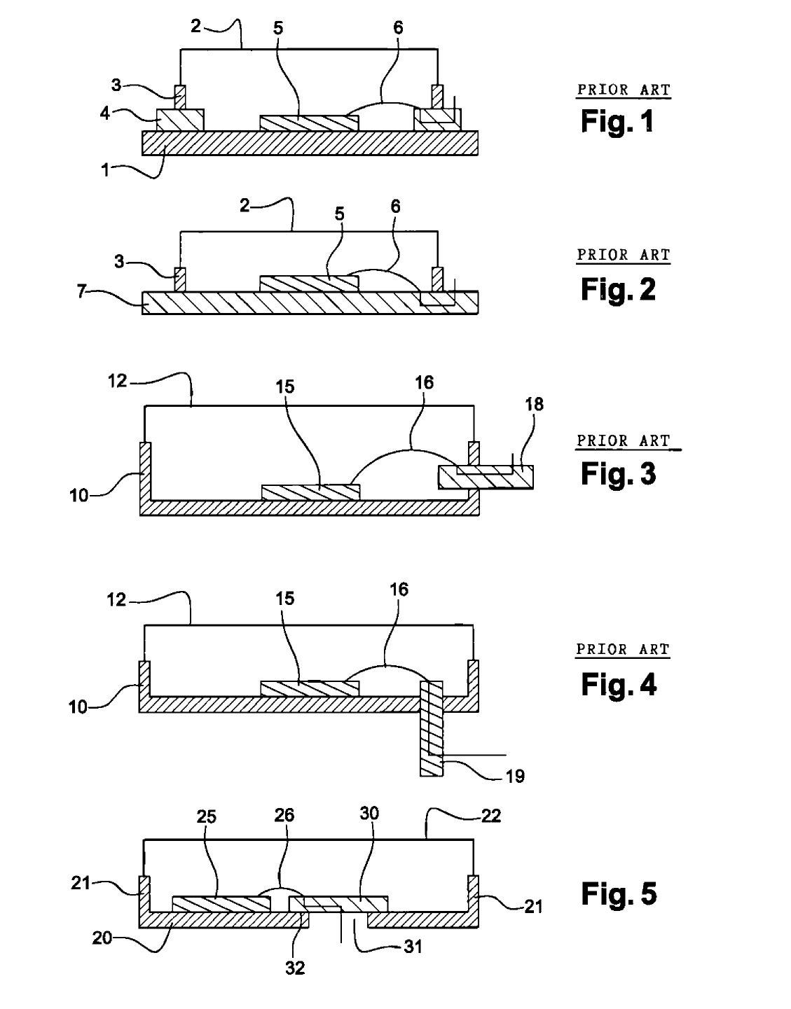

### DETAILED DESCRIPTION OF THE INVENTION

A simplified cross-section view of a package according to the present invention has thus been shown in FIG. 5. Base 20 of the package is conventionally made of Kovar®. It is closed by a cap or closing frame 22, also made of Kovar®, said cap being installed by soldering or by laser welding on the free upper end of lateral walls 21 of base 20.

The bottom of the package receives a component 25, and for example, an infrared detector, attached at this level by bonding or by high-temperature soldering.

According to a feature of the present invention, the bottom of the package is also pierced with a through opening 31.

Through opening 31 is intended to be closed with a plate 30 made of HTCC-type cofired ceramic. Plate 30 is attached by soldering at the level of lateral edge 32 defining the previously-mentioned through opening.

The width of lateral edge 32 of opening 31 of the base defining the bottom, and intended to cooperate by soldering with plate 30, is determined by standard ceramic/Kovar® soldering technologies.

Cofired ceramic plate 30 ensures, as can be observed, the electrical feedthrough for the signals transmitted by component 25 and possible conveyed to this level by means of connections 26 originating from the component.

It can thus first be observed that ceramic plate 30 has no mechanical function. It limitingly closes opening 31 of base 20 of the package to thus allow the placing of the package under vacuum and the electrical feedthrough.

Due to the very implemented principle, it should also be noted that there is no limitation of the cryostat size since there is no issue of differential expansion of the material forming the package (Kovar®) and of the ceramic plate, since the latter keeps a small size.

The transmission of electric signals may further be performed on the surface with gold tracks placed on the ceramic plate, crossing onto the other surface by vias.

Besides, it should be underlined that the Kovar®-on-ceramic soldering technique is perfectly well controlled, especially as is here the case, when it is performed face-to-face, thus optimizing the encapsulation package tightness and thus the quality of the vacuum.

The advantage of the present invention can thus be understood due to the possibilities that it provides in terms of large component encapsulation.

What is claimed is:

1. A method for forming sealed electrical feedthroughs through an encapsulation package, especially for an electronic, optical, or optoelectronic component, comprising:
forming a through opening in one of the package walls,
soldering, on this opening, a plate made of cofired ceramic having the electric connections transiting therethrough.

2. The method for forming sealed electrical feedthroughs through an encapsulation package of claim 1, wherein the cofired ceramic plate is soldered on the wall of the package, face-to-face.

3. The method for forming sealed electrical feedthroughs through an encapsulation package of claim 1, wherein the through opening is formed in the bottom of said package.

4. The method for forming sealed electrical feedthroughs through an encapsulation package of claim 3, wherein the cofired ceramic plate is soldered on the bottom of the package, face-to-face.

5. The method for forming sealed electrical feedthroughs through an encapsulation package of claim 1, wherein the package is made of a FeNiCo alloy.

6. An encapsulation package for at least one electronic, optical, or optoelectronic component, where vacuum can be made, formed of a bottom or of a base having a cap or closing frame placed thereon by soldering or welding, wherein it is provided with a through opening made at the level of its bottom, said opening being closed by means of a plate made of cofired ceramic, soldered at the level of the lateral edges defining said through opening, said plate ensuring the electrical feedthrough for the signals generated by said component.
